(19) United States
(12) Patent Application Publication
(10) Pub. No.: US 2016/0266215 A1
(43) Pub. Date: Sep. 15, 2016

(54) MAGNETIC SENSOR DEVICE

(71) Applicant: SII Semiconductor Corporation, Chiba-shi (JP)

(72) Inventor: Takahiro ITO, Chiba-shi (JP)

(21) Appl. No.: 15/062,645

(22) Filed: Mar. 7, 2016

(30) Foreign Application Priority Data
Mar. 9, 2015 (JP) 2015-046303

(51) Int. Cl. G01R 33/07

(52) U.S. Cl. CPC G01R 33/075

(57) ABSTRACT

In order to reduce a magnetic offset in a magnetic sensor using Hall elements, namely, a magnetic offset reduction circuit using a spinning current method, provided is a magnetic sensor device including: a current path switching switch that is connected to each of terminals of the Hall element, and is configured to perform switching between a first current path and a second current path; an output path switching switch that is connected to each of terminals of the Hall element, and is configured to switch a path for a Hall voltage to be output, between a first output path and a second output path; and a subtracter configured to output a difference between an output voltage of the first output path and an output voltage of the second output path, in which the first output path and the second output path have the same wiring resistance value.

This application claims priority under 35 U.S.C. §119 to Japanese Patent Application No. 2015-046303 filed on Mar. 9, 2015, the entire content of which is hereby incorporated by reference.

### BACKGROUND OF THE INVENTION

1. Field of the Invention

The present invention relates to a magnetic sensor device using Hall elements, and more specifically, to a technology of reducing a magnetic offset of a spinning-current magnetic sensor device.

2. Description of the Related Art

Hall voltages output from Hall elements include not only signal components of magnetic fields applied to the Hall elements, but also magnetic offset components. The magnetic offset is an error component generated due to various factors such as a manufacturing variation in manufacturing the Hall elements and stress applied to the Hall elements. The magnetic offset is the error component and thus greatly affects a reduction in precision of a magnetic sensor.

In Japanese Patent Application Laid-open No. 2001-337147, there is disclosed a circuit configured to reduce magnetic offset components by a spinning-current method. By the spinning current method, a difference between Hall voltages is output. One of the Hall voltages is obtained from two terminals through which no current flows when a current is caused to flow through the Hall element in a first direction. Another one of the Hall voltages is obtained from two terminals through which no current flows when a current is caused to flow through the Hall element in a second direction orthogonal to the first direction. Thus, only signal components in the first direction and the second direction are added, and the magnetic offset components are canceled out.

However, there is a problem in that, even when the spinning current method is employed, new noise components may be generated due to an influence of parasitic resistance depending on layout patterns.

FIG. 5 is an arrangement and wiring diagram of a related-art magnetic sensor device.

In FIG. 5, a current is caused to flow from SW3 to SW4 in a first direction. In a magnetic sensor using Hall elements, namely, a spinning-current magnetic offset reduction circuit, PN junction diodes D1 to D4 exist between a P-type substrate and respective N+ sources of output voltage switching N-channel field effect transistors SW5 and SW6, and leakage current slightly flows therethrough. Thus, noise components are not eliminated even through the use of the spinning-current offset reduction circuit because, if wiring resistance does not have the same value from terminals H1 to H4 of the Hall element to the N+ sources of the output voltage switching N-channel field effect transistors SW5 and SW6, a voltage drop due to the PN junction diodes varies even when the same Hall voltage is output from the Hall element, resulting in a difference in signal level between the first direction and the second direction.

### SUMMARY OF THE INVENTION

The present invention has been made in view of the problem described above, and has an object to reduce a magnetic offset by devising layout patterns in a magnetic sensor using Hall elements, namely, a spinning-current circuit configured to reduce a magnetic offset.

In order to solve the above-mentioned problem, a magnetic sensor device according to one embodiment of the present invention has the following configuration.

The magnetic sensor device includes: a current path switching switch that is connected to each of terminals of a Hall element, and is configured to switch a path between a first current path and a second current path; an output path switching switch that is connected to each of the terminals of the Hall element, and is configured to switch a path for a Hall voltage of the Hall element to be output, between a first output path and a second output path; and a subtracter configured to output a difference between an output voltage of the first output path and an output voltage of the second output path, the first output path and the second output path having the same wiring resistance value.

According to the magnetic sensor device of the one embodiment of the present invention, the wiring resistance is set to the same value from the output terminal of the Hall element to the output voltage switching switches so that a magnetic offset may be reduced.

### BRIEF DESCRIPTION OF THE DRAWINGS

FIG. 1 is an example of an arrangement and wiring diagram of a magnetic sensor device according to an embodiment of the present invention.

FIG. 2 is a diagram for illustrating details of components of a Hall voltage of the magnetic sensor device of this embodiment.

FIG. 3 is another example of the arrangement and wiring diagram of the magnetic sensor device of this embodiment.

FIG. 4 is a diagram for illustrating details of components of a Hall voltage of the magnetic sensor device of this embodiment.

FIG. 5 is an arrangement and wiring diagram of a related-art magnetic sensor device.

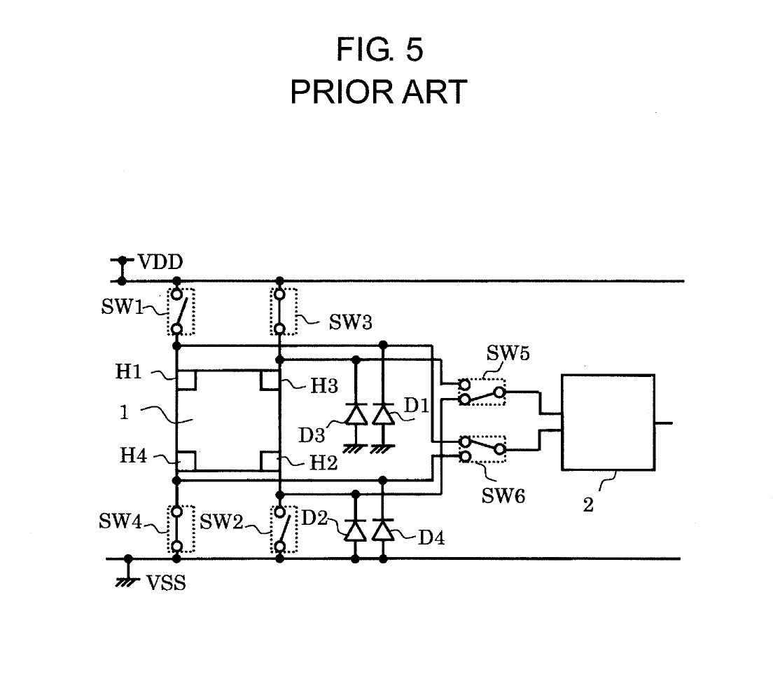

### DETAILED DESCRIPTION OF THE PREFERRED EMBODIMENTS

Now, an embodiment of the present invention is described with reference to the drawings.

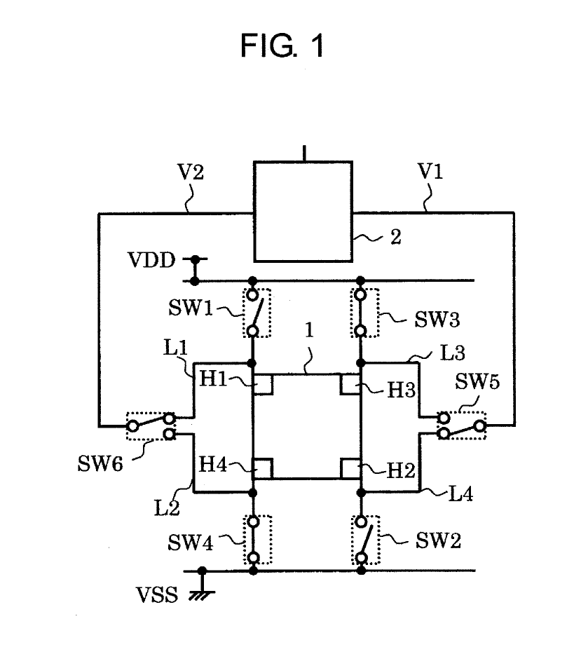

FIG. 1 is an example of an arrangement and wiring diagram of a magnetic sensor device of this embodiment.

SW5 and SW6 are arranged to be axially symmetric to an origin of a Hall element 1 with respect to an X-axis and a Y-axis. When each of wires has the same unit wiring resistance value, wiring resistance values of wires L1 to L4 become the same through setting the wires to have an equal length as illustrated in FIG. 1.

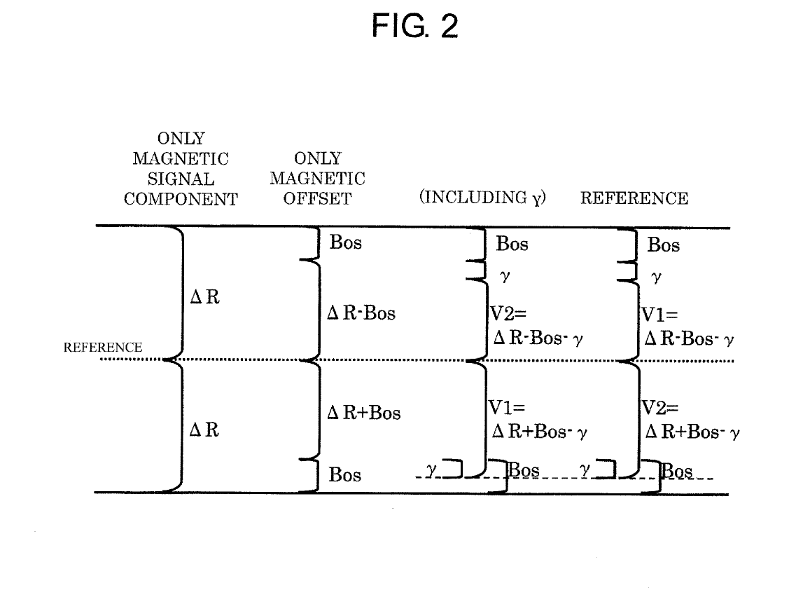

FIG. 2 is a diagram for illustrating details of components of a Hall voltage of the magnetic sensor device of this embodiment in FIG. 1.

A state in which a current is caused to flow from a terminal H3 to a terminal H4 in a first direction is represented by φ1, and a state in which a current is caused to flow from a terminal H1 to a terminal H2 in a second direction is represented by φ2. Further, an output voltage of an output voltage switching switch SW5 is represented by V1, and an output voltage of an output voltage switching switch SW6 is represented by V2. The voltage V1 under the state φ1 is represented by V1φ1, the voltage V2 under the state φ1 is represented by V2φ1, the voltage V1 under the state φ2 is represented by V1φ2, and the voltage V2 under the state φ2 is represented by V2φ2. In the following description, it is assumed that a magnetic field is applied to the magnetic sensor from the above.

The voltage V1φ1 and the voltage V2φ1 that are generated when the magnetic field is applied under the state φ1 are expressed as follows.

V1φ1=−ΔR+Bos−γ (1)

V2φ1=+ΔR−Bos−γ (2)

Further, the voltage V1φ2 and the voltage V2φ2 that are generated under the state φ2 are expressed as follows.

V1φ2=+ΔR+Bos−γ (3)

V2φ2=−ΔR−Bos−γ (1)

A result obtained by performing (expression (1)-expression (2)) by a subtracter 2 is referred to as a voltage Vφ1, and a result obtained by performing (expression (3)-expression (4)) by the subtracter 2 is referred to as a voltage Vφ2. Then, the calculations are expressed as the following expressions (5) and (6).

Vφ1=(−ΔR+Bos−γ)−(+ΔR−Bos−γ)=−2ΔR+2Bos (5)

Vφ2=(+ΔR+Bos−γ)−(−ΔR−Bos−γ)=+2ΔR+2Bos (6)

Further, Vφ2−Vφ1 is performed by the subtracter 2, to thereby obtain an output voltage of the subtracter 2 as follows.

(+2ΔR+2Bos)−(−2ΔR+2Bos)=+4ΔR (7)

Thus, only magnetic signal components are added. Magnetic offset components and a voltage drop γ due to the wires L1 to L4 are canceled out, and are not output from the subtracter 2.

Note that, as long as the wiring resistance values of the wires L1 to L4 are the same, arrangement locations such as a distance from the Hall element 1 to each of SW5 and SW6 are not limited.

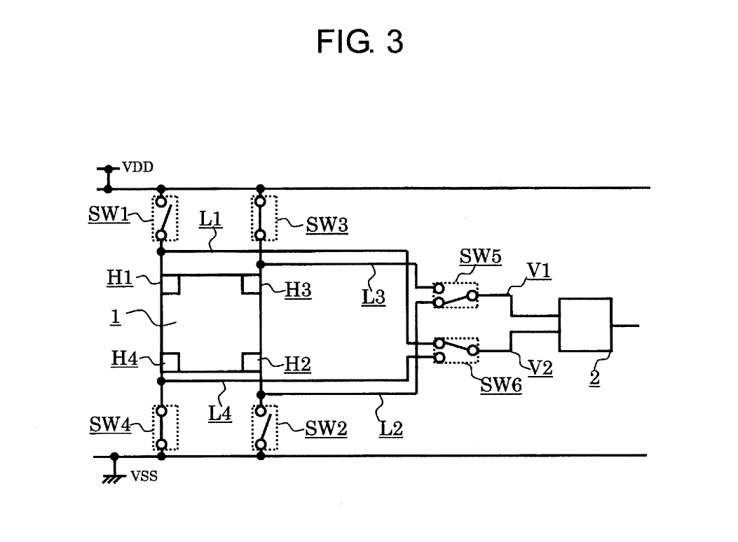

FIG. 3 is another example of an arrangement and wiring diagram of the magnetic sensor device of this embodiment.

SW5 and SW6 are arranged to be on one side with respect to the origin of the Hall element. When the wiring resistance values of the wire L1 and the wire L3 are the same, and the wiring resistance values of the wire L2 and the wire L4 are the same, a wiring resistance value between the Hall element 1 and the subtracter 2 is unchanged even when SW5 and SW6 are switched.

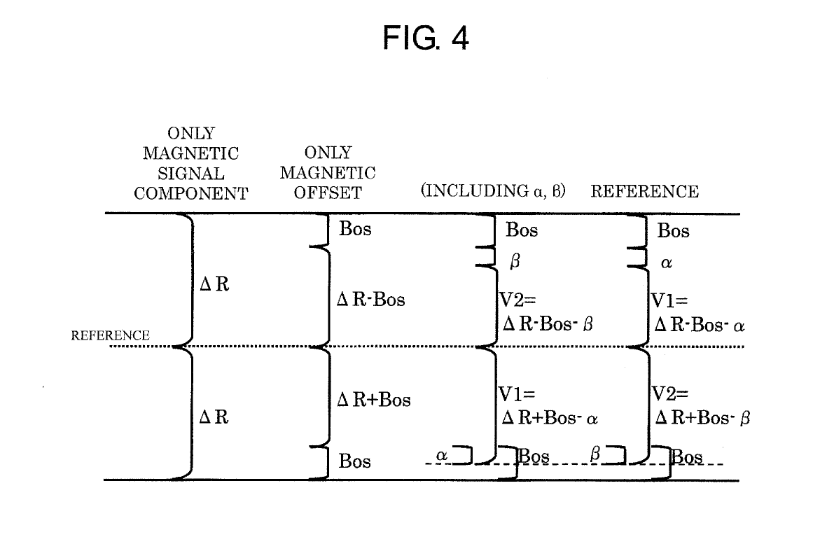

FIG. 4 is a diagram for illustrating details of components of a Hall voltage of the magnetic sensor device of this embodiment in FIG. 3.

A state in which a current is caused to flow from the terminal H3 to the terminal H4 in a first direction is represented by φ1, and a state in which a current is caused to flow from the terminal H1 to the terminal H2 in a second direction is represented by φ2. Further, an output voltage of the output voltage switching switch SW5 is represented by V1, and an output voltage of the output voltage switching switch SW6 is represented by V2. The voltage V1 under the state φ1 is represented by V1φ1, the voltage V2 under the state φ1 is represented by V2φ1, the voltage V1 under the state φ2 is represented by V1φ2, and the voltage V2 under the state φ2 is represented by V2φ2.

The voltage V1φ1 and the voltage V2φ1 that are generated when the magnetic field is applied under the state φ1 are expressed as follows.

V1φ1=−ΔR+Bos−α (8)

V2φ1=+ΔR−Bos−β (9)

Further, the voltage V1φ2 and the voltage V2φ2 that are generated under the state φ2 are expressed as follows.

V1φ2=+ΔR+Bos−α (10)

V2φ2=−ΔR−Bos−β (11)

A result obtained by performing (expression (1)-expression (2)) by the subtracter 2 is referred to as a voltage Vφ1, and a result obtained by performing (expression (3)-expression (4)) by the subtracter 2 is referred to as a voltage Vφ2. Then, the calculations are expressed as the following expressions (5) and (6).

Vφ1=(−ΔR+Bos−α)−(+ΔR−Bos−β)=−2ΔR+2Bos−α+β (12)

Vφ2=(+ΔR+Bos−α)−(−ΔR−Bos−β)=+2ΔR+2Bos−α+β (13)

Further, Vφ2−Vφ1 is performed by the subtracter 2, to thereby obtain an output voltage of the subtracter 2 as follows.

(+2ΔR+2Bos−α+β)−(−2ΔR+2Bos−α+β)=+4ΔR (14)

Thus, only signals are added. Magnetic offset components, a voltage drop a due to the wire L1 and the wire L3, and a voltage drop β due to the wire L2 and the wire L4 are canceled out, and are not output from the subtracter 2.

Note that, as long as the wiring resistance values of the wire L1 and the wire L3 are the same and the wiring resistance values of the wire L2 and the wire L4 are the same, arrangement locations such as a distance from the Hall element to each of SW5 and SW6 are not limited.

What is claimed is:

1. A magnetic sensor device, comprising:
a Hall element including two terminals on each of a high potential side and a low potential side of a power supply;
a current path switching switch that is connected to each of the terminals of the Hall element, and is configured to switch a path for a current to be caused to flow through the Hall element, between a first current path and a second current path;
an output path switching switch that is connected to each of the terminals of the Hall element, and is configured to switch a path for a Hall voltage of the Hall element to be output, between a first output path and a second output path; and
a subtracter configured to output a difference between an output voltage of the first output path and an output voltage of the second output path,
the first output path and the second output path having the same wiring resistance value.

2. A Magnetic sensor device according to claim 1, wherein the current path switching switch and the output path switching switch are arranged to be axially symmetric to the Hall element with respect to an X-axis and a Y-axis.
